(19) United States
(12) Patent Application Publication
(10) Pub. No.: US 2026/0134922 A1
(43) Pub. Date: May 14, 2026

(54) Program Operations in Memory Devices

(71) Applicant: Yangtze Memory Technologies Co., Ltd., Wuhan (CN)

(72) Inventors: Xufeng ZHOU, Wuhan (CN); Jinchi HAN, Wuhan (CN); Zhipeng DONG, Wuhan (CN)

(21) Appl. No.: 19/015,036

(22) Filed: Jan. 9, 2025

(30) Foreign Application Priority Data
Nov. 14, 2024 (CN) 202411632161.2

(51) Int. Cl. G11C 16/10; G11C 16/04; G11C 16/08; G11C 16/32

(52) U.S. Cl. CPC G11C 16/102; G11C 16/0483; G11C 16/08; G11C 16/32

(57) ABSTRACT

Example methods, memory devices, and systems for program operations in memory devices are disclosed. One example method includes applying a first voltage to a first line coupled to the first memory cell during a first time period, where the first line includes one of a source line and a bit line coupled to the first memory cell. A first programming voltage is applied to a first word line coupled to the first memory cell during a second time period after the first time period. A second voltage is applied to the first line during a third time period after the second time period, where the second voltage is higher than the first voltage. A second programming voltage is applied to the first word line during a fourth time period after the third time period, where the fourth time period is shorter than the second time period.

### CROSS-REFERENCE TO RELATED APPLICATIONS

This application claims priority to Chinese Patent Application No. 202411632161.2, filed on Nov. 14, 2024, which is hereby incorporated by reference in its entirety.

### TECHNICAL FIELD

The present disclosure relates to memory devices, systems, and methods for program operations in memory devices.

### BACKGROUND

Voltage generators can provide voltages to support operations in memory devices. An example of a memory device is a flash memory. Flash memory is a low-cost, high-density, nonvolatile solid-state storage medium that can be electrically erased and reprogrammed. Flash memory includes NOR flash memory and NAND flash memory. Various operations can be performed by flash memories, for example, read, program (write), and erase operations.

### SUMMARY

The present disclosure relates to methods, memory devices, and systems for program operations in memory devices.

Certain aspects of the subject matter described here can be implemented as a method. The method includes applying a first voltage to a first line coupled to the first memory cell during a first time period, where the first line includes one of a source line and a bit line coupled to the first memory cell. A first programming voltage is applied to a first word line coupled to the first memory cell during a second time period after the first time period. A second voltage is applied to the first line during a third time period after the second time period, where the second voltage is higher than the first voltage. A second programming voltage is applied to the first word line during a fourth time period after the third time period, where the fourth time period is shorter than the second time period.

The method can include one or more of the following features.

In some implementations, memory cells in the memory cell array are programmed in a direction from memory cells closest to bit lines of the memory cell array to memory cells closest to the source line.

In some implementations, the second programming voltage is higher than the first programming voltage.

In some implementations, a third voltage and a fourth voltage are respectively applied, during the first time period and the second time period, to a select line coupled to a select gate transistor in the memory cell array, where the third voltage is higher than the fourth voltage.

In some implementations, a fifth voltage is applied to the first word line during the first time period, where the fifth voltage is lower than the first programming voltage.

In some implementations, a sixth voltage is applied to a second word line during the first time period, where the sixth voltage is lower than the first programming voltage. A seventh voltage is applied to the second word line during the second time period, where the seventh voltage is higher than the sixth voltage.

In some implementations, an eighth voltage is applied to the first line during a fifth time period after the fourth time period, where the eighth voltage is higher than the second voltage. A third programming voltage is applied to the first word line during a sixth time period after the fifth time period, where the sixth time period is shorter than the fifth time period, and the third programming voltage is higher than the second programming voltage.

In some implementations, a ninth voltage is applied to the first line during the second time period, where the ninth voltage is higher than the first voltage.

In some implementations, the memory device is a NAND memory device.

Certain aspects of the subject matter described here can be implemented as a memory device. The memory device includes a memory cell array and a peripheral circuit coupled to the memory cell array and configured to perform operations. During a program operation of a first memory cell in the memory cell array, the operations include applying a first voltage to a first line coupled to the first memory cell during a first time period, where the first line comprises one of a source line and a bit line coupled to the first memory cell. A first programming voltage is applied to a first word line coupled to the first memory cell during a second time period after the first time period. A second voltage is applied to the first line during a third time period after the second time period, wherein the second voltage is higher than the first voltage. A second programming voltage is applied to the first word line during a fourth time period after the third time period, where the fourth time period is shorter than the second time period.

The memory device can include one or more of the following features.

In some implementations, memory cells in the memory cell array are programmed in a direction from memory cells closest to bit lines of the memory cell array to memory cells closest to the source line.

In some implementations, the second programming voltage is higher than the first programming voltage.

In some implementations, a third voltage and a fourth voltage are respectively applied, during the first time period and the second time period, to a select line coupled to a select gate transistor in the memory cell array, where the third voltage is higher than the fourth voltage.

In some implementations, a fifth voltage is applied to the first word line during the first time period, where the fifth voltage is lower than the first programming voltage.

In some implementations, a sixth voltage is applied to a second word line during the first time period, where the sixth voltage is lower than the first programming voltage. A seventh voltage is applied to the second word line during the second time period, where the seventh voltage is higher than the sixth voltage.

In some implementations, an eighth voltage is applied to the first line during a fifth time period after the fourth time period, where the eighth voltage is higher than the second voltage. A third programming voltage is applied to the first word line during a sixth time period after the fifth time period, where the sixth time period is shorter than the fifth time period, and the third programming voltage is higher than the second programming voltage.

In some implementations, a ninth voltage is applied to the first line during the second time period, where the ninth voltage is higher than the first voltage.

In some implementations, the memory device is a NAND memory device.

Certain aspects of the subject matter described here can be implemented as a memory system. The memory system includes a memory device and a controller coupled to the memory device and configured to initiate operations. The memory device includes a memory cell array and a peripheral circuit coupled to the memory cell array and configured to perform the operations. During a program operation of a first memory cell in the memory cell array, the operations include applying a first voltage to a first line coupled to the first memory cell during a first time period, where the first line comprises one of a source line and a bit line coupled to the first memory cell. A first programming voltage is applied to a first word line coupled to the first memory cell during a second time period after the first time period. A second voltage is applied to the first line during a third time period after the second time period, wherein the second voltage is higher than the first voltage. A second programming voltage is applied to the first word line during a fourth time period after the third time period, where the fourth time period is shorter than the second time period.

In some implementations, memory cells in the memory cell array are programmed in a direction from memory cells closest to bit lines of the memory cell array to memory cells closest to the source line.

The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic circuit diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates an example memory device that includes some example peripheral circuits and a memory cell array, according to some aspects of the present disclosure.

FIG. 4 illustrates example voltages of components in a memory cell array during a program loop of a memory cell in the memory cell array, according to some aspects of the present disclosure.

FIG. 5 illustrates example voltages of components in a memory cell array during three program loops of a memory cell in the memory cell array, according to some aspects of the present disclosure.

FIG. 6 illustrates example voltages of components in a memory cell array during another program loop of a memory cell in the memory cell array, according to some aspects of the present disclosure.

FIG. 7 illustrates another example of voltages of components in a memory cell array during three program loops of a memory cell in the memory cell array, according to some aspects of the present disclosure.

FIG. 8 is a flow chart of an example process for a program operation using varying program pulse widths, according to some aspects of the present disclosure.

FIG. 9 illustrates a block diagram of an example system having a memory device, according to some aspects of the present disclosure.

FIG. 10A illustrates a diagram of a memory card having a memory device, according to some aspects of the present disclosure.

FIG. 10B illustrates a diagram of a solid-state drive (SSD) having a memory device, according to some aspects of the present disclosure.

Like reference numbers and designations in the various drawings indicate like elements.

### DETAILED DESCRIPTION

During a precharge stage of a program loop in a program operation of a memory cell in a memory device, a voltage can be applied to a source line coupled to an array common source (ACS) to precharge all channels in a memory cell block that includes the memory cell, such that the potentials of all channels can be increased. Consequently, when the memory cell is being programmed during a program stage of the program loop, the channel potential of each unselected memory string in the memory cell block can have a self-boosting effect, such that the memory cells in each unselected memory string will not be programmed during the program stage. In some cases, a higher voltage applied to the source line during the precharge stage can reduce program disturb and improve E0. However, the higher voltage can also lead to larger Esum loss.

This specification relates to memory devices, systems, and methods for improving program operations of memory devices, for example, by reducing Esum loss when a relatively high voltage is applied to a source line coupled to an ACS during a precharge stage. In some cases, to reduce larger Esum loss caused by a higher voltage applied to the source line, the width of a programming pulse applied to a word line coupled to a memory cell selected for programming can be reduced during a program stage following a precharge stage that has a higher voltage applied to the source line. In some cases, the higher the voltage applied to the source line during the precharge stage, the shorter the width of the programming pulse during the program stage.

Implementations of the present disclosure can provide one or more of the following technical effects. For example, Esum loss associated with high voltage applied to a source line in a memory device can be reduced, without increasing program disturb in the memory device. As another example, programming time of each page in the memory device can be reduced. Therefore, the performance of the memory device can be improved. Additionally, over-programming due to high voltages applied to the source line can be mitigated. Furthermore, the described techniques can be implemented without hardware changes to achieve the benefits of improved performance of the memory device.

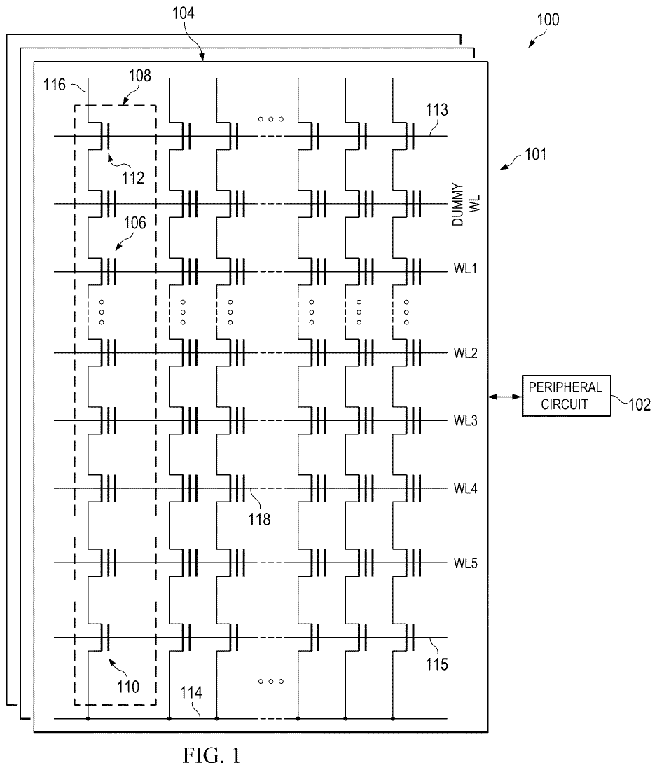

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 and DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage (e.g., 0 V) to respective DSG 112 through one or more DSG lines 113, and/or by applying a select voltage or a deselect voltage (e.g., 0 V) to respective SSG 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Vers), such as a high positive voltage (e.g., 20 V or more). In some examples, erase operation may be performed at a half-block level, a quarter-block level, or a level having any suitable number of blocks or any suitable fractions of a block. Memory cells 106 of adjacent NAND memory strings can be coupled through word lines 118 that select which row of memory cells 106 is affected by read and program operations. Each word line 118 can include a plurality of control gates (gate electrodes) at each memory cell 106 and a gate line coupling the control gates. Example word lines (WLs) shown in FIG. 1 include dummy WL, WL1, WL2, WL3, WL4, and WL5 that are between one or more DSG lines 113 and one or more SSG lines 115.

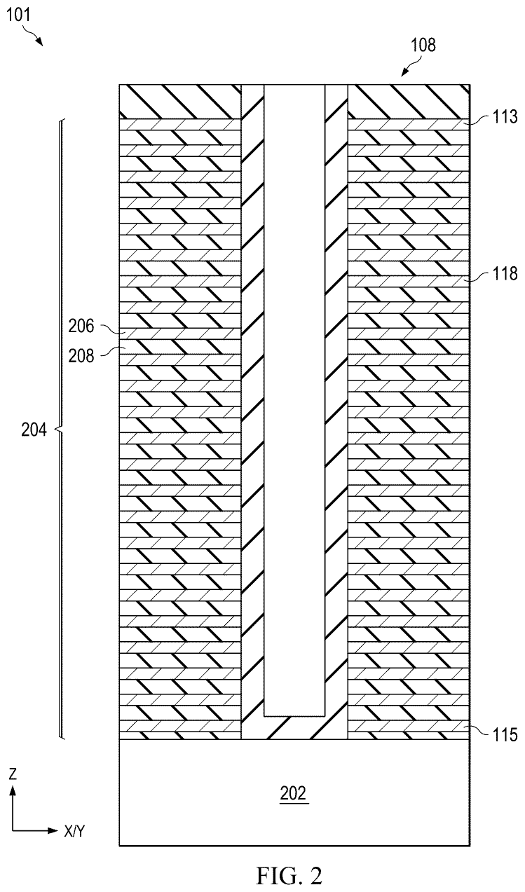

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, DSG 112, or SSG 110, and can extend laterally as DSG line 113 at the top of memory stack 204, SSG line 115 at the bottom of memory stack 204, or word line 118 between DSG line 113 and SSG line 115.

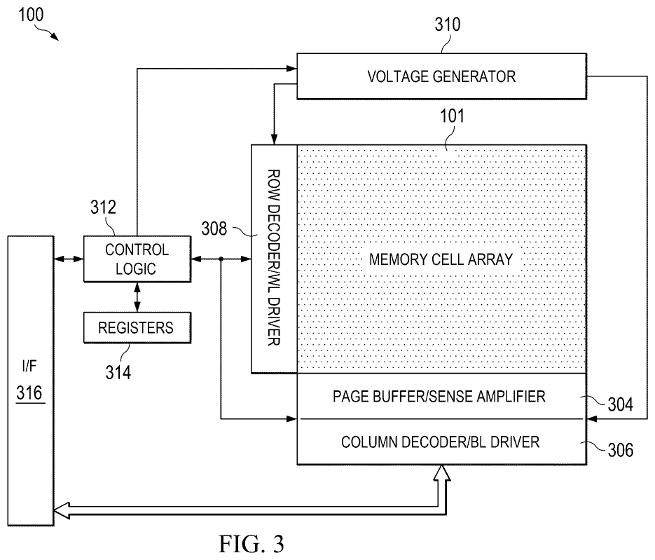

Peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each target memory cell of the memory cells 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Row decoder/word line driver 308 can be configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. The status registers of registers 314 can include one or more registers configured to store open block information indicative of the open block(s) of all blocks 104 in memory cell array 101, such as having an auto dynamic start voltage (ADSV) list. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

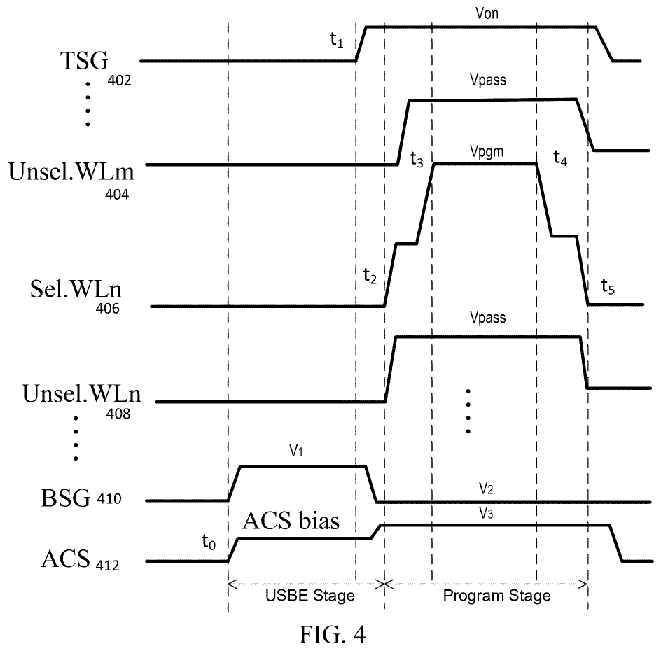

FIG. 4 illustrates example voltages of components in a memory cell array during a program loop of a memory cell in the memory cell array, according to some aspects of the present disclosure. In some implementations, a selected word line, for example, sel. WLn 406 in FIG. 4, represents a word line (i.e., first word line) coupled to a memory cell (i.e., first memory cell) selected for a program operation. An example of the program operation can be an incremental step pulse program (ISPP) operation that includes a series of program loops. Each program loop can include a program pulse with a programming voltage (i.e., first programming voltage), for example, voltage Vpgm in FIG. 4, applied to the selected word line 406 to program the memory cell to a threshold voltage. An example of the selected word line can be word line 118 in FIG. 1. An unselected word line, for example, unsel. WLm 404 or unsel. WLn 408 in FIG. 4, represents a word line (i.e., second word line) that is coupled to memory cells that are not selected for programming during the program loop. An example of unselected word line 404 or 408 can be word line 118 in FIG. 1. TSG 402 represents a selected gate line, for example, DSG line 113 in FIG. 1, coupled to one or more selected gate transistors that are turned on, for example, DSG 112 in FIG. 1, in a memory cell block. BSG 410 represents a bottom selected gate line (e.g., select line), for example, SSG line 115, that is coupled to one or more selected gate transistors, for example, SSG 110 in FIG. 1, in a memory cell block. ACS 412 represents a source line (i.e., first line), for example, common source line 114 in FIG. 1, that is coupled to an array common source (ACS).

In some implementations, during a precharge stage of a program loop in a program operation, also referred to as an unselected string boost enhancement (USBE) stage, a voltage (i.e., first voltage), for example, ACS bias in FIG. 4, can be applied to ACS 412 (e.g., between t₀ and t₂ in FIG. 4) to precharge all channels in a memory cell block, such that the potentials of all channels can be increased. Consequently, when a memory cell in a selected memory string is programmed during a program stage (e.g., between t₂ and t₅ in FIG. 4) of the program loop, the channel potential of each unselected memory string can have a self-boosting effect, such that the memory cells in each unselected memory string will not be programmed during the program stage. In some cases, higher ACS bias during the precharge stage can reduce program disturb and improve E0, while leading to larger Esum loss. In some cases, the memory cells in the memory cell block are programmed in a direction from memory cells closest to bit lines of the memory cell array to memory cells closest to the source line.

In some implementations, to reduce larger Esum loss caused by higher ACS bias, the width of a programming pulse applied to sel. WLn 406 can be reduced during a program stage following a precharge stage that has a higher ACS bias applied to ACS 412. For example, the time period between t₃ and t₄ in FIG. 4 (i.e., second time period), when a programming voltage Vpgm is applied to sel. WLn 406, can be shortened when a higher ACS bias is applied during the time period between t₀ and t₂ in FIG. 4 (i.e., first time period). Consequently, the programming time between t₂ and t₅ in FIG. 4 can be reduced. In some cases, the higher the ACS bias applied during the precharge stage, the shorter the width of the programming pulse (between t₃ and t₄ in FIG. 4) during the program stage. In some cases, the higher the programming voltage Vpgm (between t₃ and t₄ in FIG. 4) during the program stage, the shorter the width of the programming pulse (between t₃ and t₄ in FIG. 4) during the program stage. In some cases, the programming voltage Vpgm can be higher than the voltage (i.e., fifth voltage) applied to sel. WLn 406 during the precharge stage (between t₀ and t₂ in FIG. 4).

In some implementations, a voltage V₁ (i.e., third voltage) can be applied to BSG 410 during the precharge stage of the program loop, for example, between t₀ and t₂ in FIG. 4, to precharge all channels in a memory cell block.

In some implementations, a voltage V₂ (i.e., fourth voltage) can be applied to BSG 410 during the program stage (e.g., between t₂ and t₅ in FIG. 4) to turn off one or more select gate transistors coupled to BSG 410. In some cases, the voltage V₂ can be lower than the voltage V₁.

In some implementations, a voltage V₃ (i.e., ninth voltage) can be applied to ACS 412 during the program stage of the program loop, for example, between t₂ and t₅ in FIG. 4, where the voltage V₃ is higher than the ACS bias applied during the precharge stage.

In some implementations, during a program stage (e.g., between t₂ and t₅ in FIG. 4) of a program loop in a program operation, a voltage Von can be applied to TSG 402 to turn on one or more selected gate transistors coupled to TSG 402 and to a memory cell selected for the program operation.

In some implementations, during a program stage (e.g., between t₂ and t₅ in FIG. 4) of a program loop in a program operation, a voltage Vₚₐₛₛ (i.e., seventh voltage) can be applied to an unselected word line, for example, unsel. WLₘ 404 or unsel. WLₙ 408, such that memory cells coupled to the unselected word line are not programmed during the program operation.

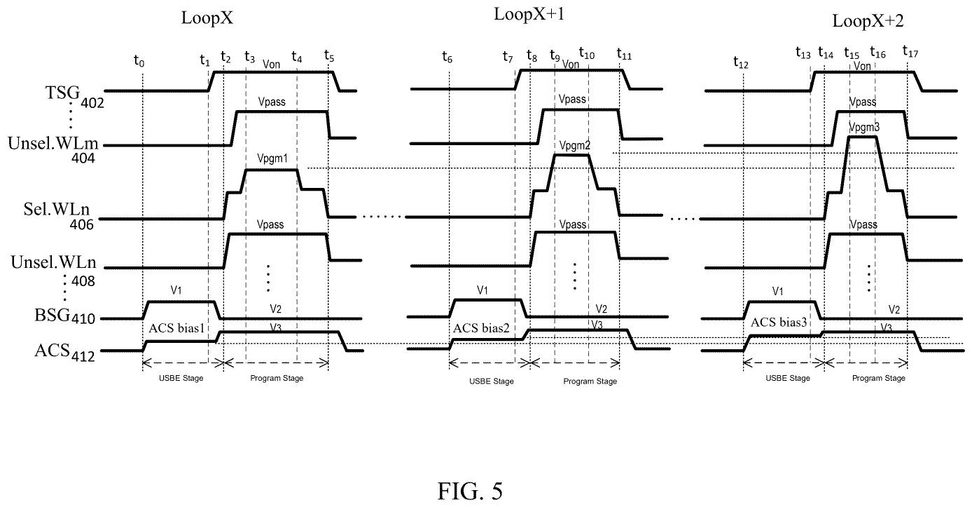

FIG. 5 illustrates example voltages of components in a memory cell array during three program loops of a memory cell in the memory cell array, according to some aspects of the present disclosure. The three program loops in FIG. 5, i.e., loopX, loopX+1, and loopX+2, are three program loops in a program operation of the memory cell. An example of the program operation is an ISPP operation that includes multiple program loops. For each of the three program loops in FIG. 5, voltage conditions of some components in the memory cell array, for example, TSG 402, unsel. WLm 404, unsel. WLn 408, and BSG 410, are identical to their counterparts in FIG. 4. Voltage conditions of other components, for example, sel. WLn 406 and ACS 412, are specific for each of the three program loops in FIG. 5.

For example, the programming voltage Vpgm2 (i.e., second programming voltage) applied to sel. WLn 406 between t₉ and t₁₀ (i.e., fourth time period) during loopX+1 can be higher than the programming voltage Vpgm1 (i.e., first programming voltage) applied to sel. WLn 406 between t₃ and t₄ (i.e., second time period) during loopX. The programming voltage Vpgm3 (i.e., third programming voltage) applied to sel. WLn 406 between t₁₅ and t₁₆ (i.e., sixth time period) during loopX+2 can be higher than the programming voltage Vpgm2 (i.e., second programming voltage) applied to sel. WLn 406 between t₉ and t₁₀ (i.e., fourth time period) during loopX+1.

In some implementations, the voltage ACS bias2 (i.e., second voltage) applied to ACS 412 during the USBE stage (i.e., third time period) of loopX+1 is higher than the voltage ACS bias1 (i.e., first voltage) applied to ACS 412 during the USBE stage (i.e., first time period) of loopX. To reduce larger Esum loss caused by higher ACS bias, the width of the programming pulse applied to sel. WLn 406 during the program stage of loopX+1, for example, between t₉ and t₁₀ in FIG. 5, is shorter than the width of the programming pulse applied to sel. WLn 406 during the program stage of loopX, for example, between t₃ and t₄ in FIG. 5. Consequently, the programming time between t₈ and t₁₁ in loopX+1 is shorter than the programming time between t₂ and t₅ in loopX. In some cases, if ACS bias2 is 0.6V higher than ACS bias1, the width of the programming pulse between t₉ and t₁₀ in FIG. 5 can be 1% shorter than the width of the programming pulse between t₃ and t₄ in FIG. 5.

In some implementations, the voltage ACS bias3 (i.e., eighth voltage) applied to ACS 412 during the USBE stage of loopX+2 (i.e., fifth time period) is higher than the voltage ACS bias2 applied to ACS 412 during the USBE stage of loopX+1. To reduce larger Esum loss caused by higher ACS bias, the width of the programming pulse applied to sel. WLn 406 during the program stage of loopX+2, for example, between t₁₅ and t₁₆ in FIG. 5 (i.e., sixth time period), is shorter than the width of the programming pulse applied to sel. WLn 406 during the program stage of loopX+1, for example, between t₉ and t₁₀ in FIG. 5. Consequently, the programming time between t₁₄ and t₁₇ in loopX+2 is shorter than the programming time between t₈ and t₁₁ in loopX+1. Therefore, programming time of a program loop can decrease as the program loop number associated with the program loop increases, thus reducing the overall programming time of each page in the memory cell array.

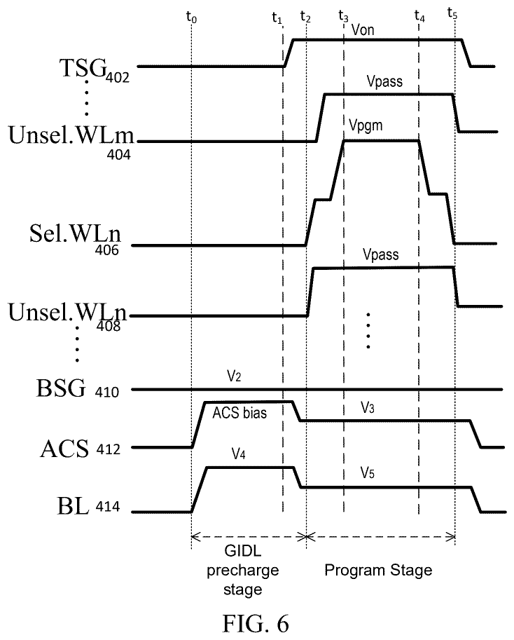

FIG. 6 illustrates example voltages of components in a memory cell array during another program loop of a memory cell in the memory cell array, according to some aspects of the present disclosure. Voltage conditions of some components in the memory cell array, for example, TSG 402, unsel. WLm 404, unsel. WLn 408, and sel. WLn 406, are identical to their counterparts in FIG. 4. Voltage conditions of other components, for example, BSG 410 and ACS 412, are specific for the program loop in FIG. 6. FIG. 6 also illustrates voltage conditions of a bit line (i.e., BL 414) coupled to a memory string that includes the memory cell selected for a program operation.

In some implementations, during a precharge stage of a program loop in a program operation, also referred to as a gate-induced drain leakage (GIDL) precharge stage, a voltage V₄ (i.e., first voltage) can be applied to BL 414 (e.g., between t₀ and t₂ in FIG. 6), to precharge all channels in a memory cell block, such that the potentials of all channels can be increased. Consequently, when a memory cell in a selected memory string is programmed during a program stage (e.g., between t₂ and t₅ in FIG. 6) of the program loop, the channel potential of each unselected memory string can have a self-boosting effect, such that the memory cells in each unselected memory string will not be programmed during the program stage. In some cases, higher voltage V₄ during the precharge stage can reduce program disturb and improve E0, while leading to larger Esum loss. In some implementations, the memory cells in the memory cell block are programmed in a direction from memory cells closest to the source line of the memory cell array to memory cells closest to bit lines of the memory cell array.

In some implementations, to reduce larger Esum loss caused by higher voltage V₄, the width of a programming pulse applied to sel. WLn 406 can be reduced during a program stage following a precharge stage that has a higher voltage V₄ applied to BL 414. For example, the time period between t₃ and t₄ in FIG. 6 (i.e., second time period), when a programming voltage Vpgm is applied to sel. WLn 406, can be shortened when a higher voltage V₄ is applied during the time period between t₀ and t₂ in FIG. 6 (i.e., first time period). Consequently, the programming time between t₂ and t₅ in FIG. 6 can be reduced. In some cases, the higher the voltage V₄ applied during the precharge stage, the shorter the width of the programming pulse (between t₃ and t₄ in FIG. 6) during the program stage. In some cases, the higher the programming voltage Vpgm (between t₃ and t₄ in FIG. 6) during the program stage, the shorter the width of the programming pulse (between t₃ and t₄ in FIG. 6) during the program stage. In some cases, the programming voltage Vpgm can be higher than the voltage (i.e., fifth voltage) applied to sel. WLn 406 during the precharge stage (between t₀ and t₂ in FIG. 6).

In some implementations, a voltage V₅ can be applied to BL 414 during the program stage of the program loop, for example, between t₂ and t₅ in FIG. 6, where the voltage V₅ is lower than the voltage V₄ applied during the GIDL precharge stage.

In some implementations, a voltage V₂ can be applied to BSG 410 during the program loop, for example, between t₀ and t₅ in FIG. 6, to turn off one or more select gate transistors coupled to BSG 410.

In some implementations, during the GIDL precharge stage, an ACS bias can be applied to ACS 412 during the GIDL precharge stage (e.g., between t₀ and t₂ in FIG. 6).

In some implementations, a voltage V₃ can be applied to ACS 412 during the program stage of the program loop, for example, between t₂ and t₅ in FIG. 6, where the voltage V₃ is lower than the ACS bias applied during the GIDL precharge stage.

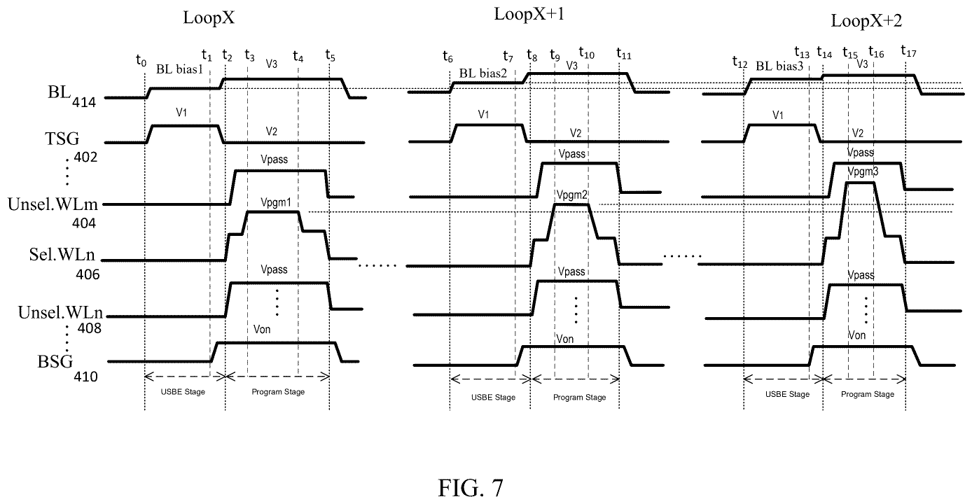

FIG. 7 illustrates another example of voltages of components in a memory cell array during three program loops of a memory cell in the memory cell array, according to some aspects of the present disclosure. The three program loops in FIG. 7, i.e., loopX, loopX+1, and loopX+2, are three program loops in a program operation of the memory cell. An example of the program operation is an ISPP operation that includes multiple program loops. For each of the three program loops in FIG. 7, voltage conditions of some components in the memory cell array, for example, unsel. WLm 404 and unsel. WLn 408, are identical to their counterparts in FIG. 4. Voltage conditions of TSG 402 in each of the three program loops in FIG. 7 are identical to voltage conditions of BSG 410 in FIG. 4. Voltage conditions of BSG 410 in each of the three program loops in FIG. 7 are identical to voltage conditions of TSG 402 in FIG. 4. Voltage conditions of other components, for example, BL 414 (a bit line coupled to a memory string that includes the memory cell selected for the program operation) and sel. WLn 406, are specific for each of the three program loops in FIG. 7.

For example, the programming voltage Vpgm2 (i.e., second programming voltage) applied to sel. WLn 406 between t₉ and t₁₀ (i.e., fourth time period) during loopX+1 can be higher than the programming voltage Vpgm1 (i.e., first programming voltage) applied to sel. WLn 406 between t₃ and t₄ (i.e., second time period) during loopX. The programming voltage Vpgm3 (i.e., third programming voltage) applied to sel. WLn 406 between t₁₅ and t₁₆ (i.e., sixth time period) during loopX+2 can be higher than the programming voltage Vpgm2 (i.e., second programming voltage) applied to sel. WLn 406 between t₉ and t₁₀ (i.e., fourth time period) during loopX+1.

In some implementations, the voltage BL bias2 (i.e., second voltage) applied to BL 414 during the USBE stage (i.e., third time period) of loopX+1 is higher than the voltage BL bias1 (i.e., first voltage) applied to BL 414 during the USBE stage (i.e., first time period) of loopX. To reduce larger Esum loss caused by higher BL bias, the width of the programming pulse applied to sel. WLn 406 during the program stage of loopX+1, for example, between t₉ and t₁₀ in FIG. 7, is shorter than the width of the programming pulse applied to sel. WLn 406 during the program stage of loopX, for example, between t₃ and t₄ in FIG. 7. Consequently, the programming time between t₈ and t₁₁ in loopX+1 is shorter than the programming time between t₂ and t₅ in loopX. In some cases, if BL bias2 is 0.6V higher than BL bias1, the width of the programming pulse between t₉ and t₁₀ in FIG. 7 can be 1% shorter than the width of the programming pulse between t₃ and t₄ in FIG. 7.

In some implementations, the voltage BL bias3 (i.e., eighth voltage) applied to BL 414 during the USBE stage of loopX+2 (i.e., fifth time period) is higher than the voltage BL bias2 applied to BL 414 during the USBE stage of loopX+1. To reduce larger Esum loss caused by higher BL bias, the width of the programming pulse applied to sel. WLn 406 during the program stage of loopX+2, for example, between t₁₅ and t₁₆ in FIG. 7 (i.e., sixth time period), is shorter than the width of the programming pulse applied to sel. WLn 406 during the program stage of loopX+1, for example, between t₉ and t₁₀ in FIG. 7. Consequently, the programming time between t₁₄ and t₁₇ in loopX+2 is shorter than the programming time between t₈ and t₁₁ in loopX+1. Therefore, programming time of a program loop can decrease as the program loop number associated with the program loop increases, thus reducing the overall programming time of each page in the memory cell array.

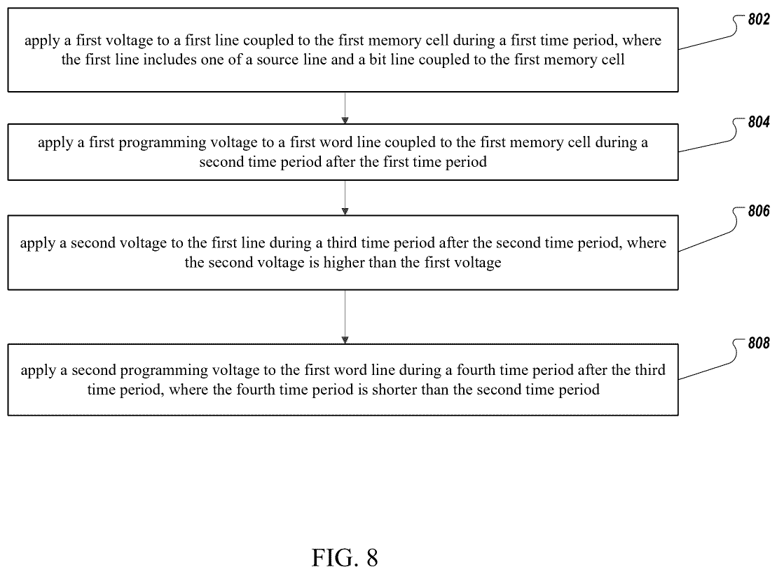

FIG. 8 is a flow chart of an example process 800 for a program operation using varying program pulse widths, according to some aspects of the present disclosure. Process 800 can be performed by any suitable device or system as described herein, for example, according to the example techniques described with respect to FIGS. 4-8. For example, process 800 can be performed by a memory device, such as memory device 100. The memory device can include a memory cell array, such as, memory cell array 101, and a peripheral circuit 102. The memory device can be a part of a memory system, such as memory system 902. The operations shown in process 800 may not be exhaustive and that other operations can be performed as well before, after, or in between any of the illustrated operations. Further, some of the operations may be performed simultaneously, or in a different order than shown in FIG. 8. In some implementations, some of the operations may be performed by or one or more components of a device or a system, such as, a peripheral circuit of the memory device.

At 802, a first voltage is applied to a first line coupled to the first memory cell during a first time period, where the first line includes one of a source line and a bit line coupled to the first memory cell.

At 804, a first programming voltage is applied to a first word line coupled to the first memory cell during a second time period after the first time period.

At 806, a second voltage is applied to the first line during a third time period after the second time period, where the second voltage is higher than the first voltage.

At 808, a second programming voltage is applied to the first word line during a fourth time period after the third time period, where the fourth time period is shorter than the second time period.

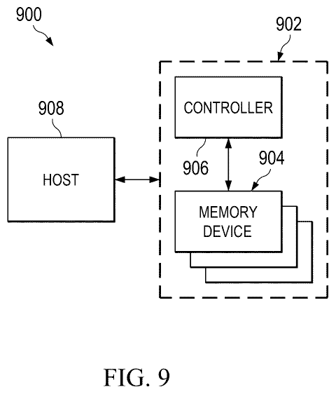

FIG. 9 illustrates a block diagram of an example system 900 having a memory device, according to some aspects of the present disclosure. System 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, system 900 can include a host 908 and a memory system 902 having one or more memory devices 904 and a memory controller 906. Host 908 can be a processor of an electronic device, such as a central processing unit (CPU), or a system-on-chip (SoC), such as an application processor (AP). Host 908 can be configured to send or receive data to or from memory devices 904.

Memory device 904 can be any memory device disclosed in the present disclosure. Memory controller 906 is coupled to memory device 904 and host 908 and is configured to control memory device 904, according to some implementations. Memory controller 906 can manage the data stored in memory device 904 and communicate with host 908. In some implementations, memory controller 906 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed for operating in a high duty-cycle environment SSDs or embedded multi-media-cards (eMMCs) used as data storage for mobile devices, such as smartphones, tablets, laptop computers, etc., and enterprise storage arrays. Memory controller 906 can be configured to control operations of memory device 904, such as read, erase, and program operations. Memory controller 906 can also be configured to manage various functions with respect to the data stored or to be stored in memory device 904 including, but not limited to bad-block management, garbage collection, logical-to-physical address conversion, wear leveling, etc. In some implementations, memory controller 906 is further configured to process error correction codes (ECCs) with respect to the data read from or written to memory device 904. Any other suitable functions may be performed by memory controller 906 as well, for example, formatting memory device 904.

Memory controller 906 can communicate with an external device (e.g., host 908) according to a particular communication protocol. For example, memory controller 906 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

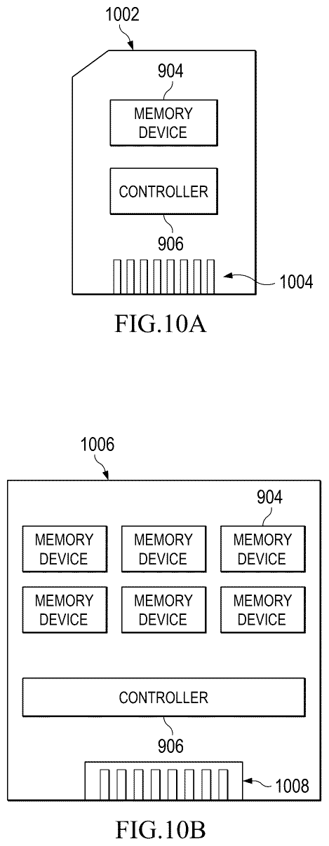

Memory controller 906 and one or more memory devices 904 can be integrated into various types of storage devices, for example, be included in the same package, such as a universal Flash storage (UFS) package or an eMMC package. That is, memory system 902 can be implemented and packaged into different types of end electronic products. In one example shown in FIG. 10A, memory controller 906 and a single memory device 904 may be integrated into a memory card 1002. Memory card 1002 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1002 can further include a memory card connector 1004 coupling memory card 1002 with a host (e.g., host 908 in FIG. 9). In another example shown in FIG. 10B, memory controller 906 and multiple memory devices 904 may be integrated into an SSD 1006. SSD 1006 can further include an SSD connector 1008 coupling SSD 1006 with a host (e.g., host 908 in FIG. 9). In some implementations, the storage capacity and/or the operation speed of SSD 1006 is greater than those of memory card 1002.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory device, comprising:
a memory cell array; and
a peripheral circuit coupled to the memory cell array and configured to perform operations comprising:
during a program operation of a first memory cell in the memory cell array:
applying a first voltage to a first line coupled to the first memory cell during a first time period, wherein the first line comprises one of a source line and a bit line coupled to the first memory cell;
applying a first programming voltage to a first word line coupled to the first memory cell during a second time period after the first time period;
applying a second voltage to the first line during a third time period after the second time period, wherein the second voltage is higher than the first voltage; and
applying a second programming voltage to the first word line during a fourth time period after the third time period, wherein the fourth time period is shorter than the second time period.

2. The memory device according to claim 1, wherein memory cells in the memory cell array are programmed in a direction from memory cells closest to bit lines of the memory cell array to memory cells closest to the source line.

3. The memory device according to claim 1, wherein the second programming voltage is higher than the first programming voltage.

4. The memory device according to claim 1, wherein the operations further comprise:
applying, during the first time period and the second time period, a third voltage and a fourth voltage respectively to a select line coupled to a select gate transistor in the memory cell array, wherein the third voltage is higher than the fourth voltage.

5. The memory device according to claim 1, wherein the operations further comprise:
applying a fifth voltage to the first word line during the first time period, wherein the fifth voltage is lower than the first programming voltage.

6. The memory device according to claim 1, wherein the operations further comprise:
applying a sixth voltage to a second word line during the first time period, wherein the sixth voltage is lower than the first programming voltage; and
applying a seventh voltage to the second word line during the second time period, wherein the seventh voltage is higher than the sixth voltage.

7. The memory device according to claim 1, wherein the operations further comprise:
applying an eighth voltage to the first line during a fifth time period after the fourth time period, wherein the eighth voltage is higher than the second voltage; and
applying a third programming voltage to the first word line during a sixth time period after the fifth time period, wherein the sixth time period is shorter than the fifth time period, and the third programming voltage is higher than the second programming voltage.

8. The memory device according to claim 1, wherein the operations further comprise:
applying a ninth voltage to the first line during the second time period, wherein the ninth voltage is higher than the first voltage.

9. The memory device according to claim 1, wherein the memory device is a NAND memory device.

10. A method, comprising:
applying a first voltage to a first line coupled to a first memory cell in a memory cell array of a memory device during a first time period, wherein the first line comprises one of a source line and a bit line coupled to the first memory cell;
applying a first programming voltage to a first word line coupled to the first memory cell during a second time period after the first time period;
applying a second voltage to the first line during a third time period after the second time period, wherein the second voltage is higher than the first voltage; and
applying a second programming voltage to the first word line during a fourth time period after the third time period, wherein the fourth time period is shorter than the second time period.

11. The method according to claim 10, wherein memory cells in the memory cell array are programmed in a direction from memory cells closest to bit lines of the memory cell array to memory cells closest to the source line.

12. The method according to claim 10, wherein the second programming voltage is higher than the first programming voltage.

13. The method according to claim 10, wherein the method further comprises:
applying, during the first time period and the second time period, a third voltage and a fourth voltage respectively to a select line coupled to a select gate transistor in the memory cell array, wherein the third voltage is higher than the fourth voltage.

14. The method according to claim 10, wherein the method further comprises:
applying a fifth voltage to the first word line during the first time period, wherein the fifth voltage is lower than the first programming voltage.

15. The method according to claim 10, wherein the method further comprises:
applying a sixth voltage to a second word line during the first time period, wherein the sixth voltage is lower than the first programming voltage; and
applying a seventh voltage to the second word line during the second time period, wherein the seventh voltage is higher than the sixth voltage.

16. The method according to claim 10, wherein the method further comprises:
applying an eighth voltage to the first line during a fifth time period after the fourth time period, wherein the eighth voltage is higher than the second voltage; and
applying a third programming voltage to the first word line during a sixth time period after the fifth time period, wherein the sixth time period is shorter than the fifth time period, and the third programming voltage is higher than the second programming voltage.

17. The method according to claim 10, wherein the method further comprises:
applying a ninth voltage to the first line during the second time period, wherein the ninth voltage is higher than the first voltage.

18. The method according to claim 10, wherein the memory device is a NAND memory device.

19. A memory system, comprising:
a memory device, comprising:
a memory cell array; and
a peripheral circuit coupled to the memory cell array and configured to perform operations comprising:
during a program operation of a first memory cell in the memory cell array:
applying a first voltage to a first line coupled to the first memory cell during a first time period, wherein the first line comprises one of a source line and a bit line coupled to the first memory cell;
applying a first programming voltage to a first word line coupled to the first memory cell during a second time period after the first time period;
applying a second voltage to the first line during a third time period after the second time period, wherein the second voltage is higher than the first voltage; and
applying a second programming voltage to the first word line during a fourth time period after the third time period, wherein the fourth time period is shorter than the second time period; and
a controller coupled to the memory device and configured to send one or more signals to the memory device to initiate the operations.

20. The memory system according to claim 19, wherein memory cells in the memory cell array are programmed in a direction from memory cells closest to bit lines of the memory cell array to memory cells closest to the source line.
